(19) United States
(12) Patent Application Publication
(10) Pub. No.: US 2013/0000712 A1
(43) Pub. Date: Jan. 3, 2013

(54) SOLAR CELL DEVICE AND PACKAGING METHOD THEREOF

(76) Inventors: Zun-Hao SHIH, Taoyuan County (TW); Yueh-Mu Lee, Taoyuan County (TW); Hwen-Fen Hong, Taoyuan County (TW)

(21) Appl. No.: 13/243,456

(22) Filed: Sep. 23, 2011

(30) Foreign Application Priority Data
Jun. 30, 2011 (TW) 100123224

(51) Int. Cl. H01L 31/0224; H01L 31/18

(52) U.S. Cl. 136/256; 438/64; 257/E31.124

(57) ABSTRACT

The present invention discloses a solar cell device and a packaging method thereof. The solar cell device applies to a concentrator photovoltaic cell, and comprises a circuit substrate, a solar cell chip, and an electrode plate. The two sides of the lower surface of the electrode plate respectively have an electronic conducting element. A positive electrode plate disposed on the circuit substrate is electrically connected with a back electrode disposed on the lower surface of the solar cell chip. Through each conducting element of the electrode plate, front electrodes disposed respectively on the two sides of the upper surface of the solar cell chip are connected with a negative electrode plate disposed on the circuit substrate.

### CROSS-REFERENCE TO RELATED APPLICATION

This application claims the benefit of Taiwan Patent Application No. 100123224, filed on Jun. 30, 2011, in the Taiwan Intellectual Property Office, the disclosure of which is incorporated herein in its entirety by reference.

### BACKGROUND OF THE INVENTION

1. Field of the Invention

The present invention relates to a solar cell device and a packaging method thereof, in particular to a concentrator photovoltaic cell and its packaging method.

2. Description of the Related Art

At present, gold wire bonding is applied to the manufacturing process of concentrator photovoltaic cell devices. FIG. 1 is a diagram of the structure of the conventional concentrator photovoltaic cells. As illustrated in the diagram, the conventional process is to solder a back electrode 21 of a solar cell chip 2 to a positive electrode plate 10 of a circuit substrate 1. A gold wire 4 is applied to connect a front electrode 20 of a solar cell chip 2 to a negative electrode plate 11 of a circuit substrate 1. To prevent the solar cell chip 2 from being scratched or adhered by undesired substance, a layer of high light-transmissive silicone 5 can be applied to protect the surface of the solar cell chip 2. The high light-transmissive silicone 5 has the properties of low thickness and high-flow liquidity, which tends to spread around. To prevent the light-transmissive silicone from spreading, the periphery of the solar cell chip 2 is either filled with a silicone 6 with high thickness and low-flow liquidity or a rubber fence with the same function. After the silicone 5 had been filled into the fence around solar cell chip 2, a glass substrate 7 is applied as a cover to prevent foreign substance from attaching to the silicone 5.

However, such a process causes the gold wire to bend and form an arc, which becomes a 3-dimensional irregular structure in the cell device that tends to produce bubbles during the silicone filling process. The bubbles will affect the volume of sunlight entering the cell.

Moreover, in the silicone filling process, the height of the filled silicone must be higher than the gold arc and cover the gold wire. This process creates a distance between the glass substrates and the solar cell chip, leading to an increase of distance between the solar cell chip surface and the light concentrating device. The increased distance reduces the light concentrating effect, and thus, affecting the electricity conversion rate.

### SUMMARY OF THE INVENTION

To overcome the problems of the conventional concentrator photovoltaic cells, the present invention seeks to provide a solar cell device which applies an electrode plate to replace the gold wire of the conventional device for electrically connecting with the solar cell chip and the circuit substrate. Such a design eliminates the bubbles produced during the silicone filling process and the distance between the surface of the solar cell chip and the light concentrating device to prevent from the reduction of electricity conversion rate resulted from ineffective light concentrating function of the conventional photovoltaic devices.

The present invention comprises a circuit substrate, a positive electrode plate, a negative electrode plate, a solar cell chip and an electrode plate with an electronic conducting element on its two sides respectively. The positive and negative electrode plates are located separately on the die area of the circuit substrate, with the negative electrode plate disposed on the two sides of the positive electrode plate. A front electrode is disposed respectively on the two sides of the upper surface of the solar cell chip, while a back electrode disposed on the lower surface of the solar cell chip. A positive electrode plate is electrically connected with a back electrode disposed on the lower surface of the solar cell chip. Each electronic conducting element electrically connects with the front electrodes disposed respectively on the two sides of the upper surface of the solar cell chip and a negative electrode plate disposed on the die area respectively.

Wherein, the back electrode is connected with the positive electrode plate with the first electricity conducting adhesive material. Each electronic conducting element electrically connects with each front electrode and the negative electrode plate respectively through the second electricity conducting adhesive material.

The melting point of the first electricity conducting adhesive material is higher than the melting point of the second electricity conducting adhesive material.

Wherein, there is a light-transmissive transparent colloid material between the electrode plate and the solar cell chip.

Wherein, the present invention provides a solar cell device packaging method, which is applicable to concentrator photovoltaic cells. The solar cell device comprises a circuit substrate, a solar cell chip, and an electrode plate. The steps are described as follows: disposing a positive electrode plate on the die area of the circuit substrate; disposing a negative electrode corresponding to the two sides of the positive electrode plate; disposing respectively a front electrode on the two sides of the upper surface of the solar cell chip; placing a back electrode on the lower surface of the solar cell chip; electrically connecting the back electrode and the positive electrode plate; installing an electronic conducting element respectively on the two sides of the lower surface of the electrode plate; and electrically connecting each front electrode and the negative electrode plate respectively with each conducting element.

Wherein, the process includes the following steps: electrically connecting the back electrode and positive electrode plate with the first electricity conducting adhesive material; and electrically connecting each electronic conducting element with each front electrode and the negative electrode plate respectively with the second electricity conducting adhesive material.

Wherein, the melting point of the first electricity conducting adhesive material is higher than the melting point of the second electricity conducting adhesive material.

Wherein, the process includes the following steps: filling the space between electrode plate and solar cell chip with a light-transmissive colloid material.

In summation, the present invention has one or more of the following advantages:

(1) With the electronic conducting elements, the positive and negative electrodes of the solar cell chip and the positive and negative electrodes of the circuit substrate can be connected each other through the electrode plate to form a circuit loop. This simplifies the packaging process and reduces the costs.

(2) The solar cell device makes use of the electronic conducting elements to connect the positive and negative electrodes of the solar cell chip and the positive and negative electrodes of the circuit substrate to form a circuit loop. It overcomes the bubble problem happened in a conventional manufacturing process.

(3) The solar cell device connects the positive and negative electrodes of the solar cell chip and the positive and negative electrodes of the circuit substrate with the electronic conducting elements on the electrode plate to form a circuit loop, and thus shortening the distance between the electrode plate and the solar cell chip, and resulting in a shorter distance between the light concentrating device and the surface of the solar cell chip.

### BRIEF DESCRIPTION OF THE DRAWINGS

FIG. 1 is a schematic diagram of the conventional solar cell device;

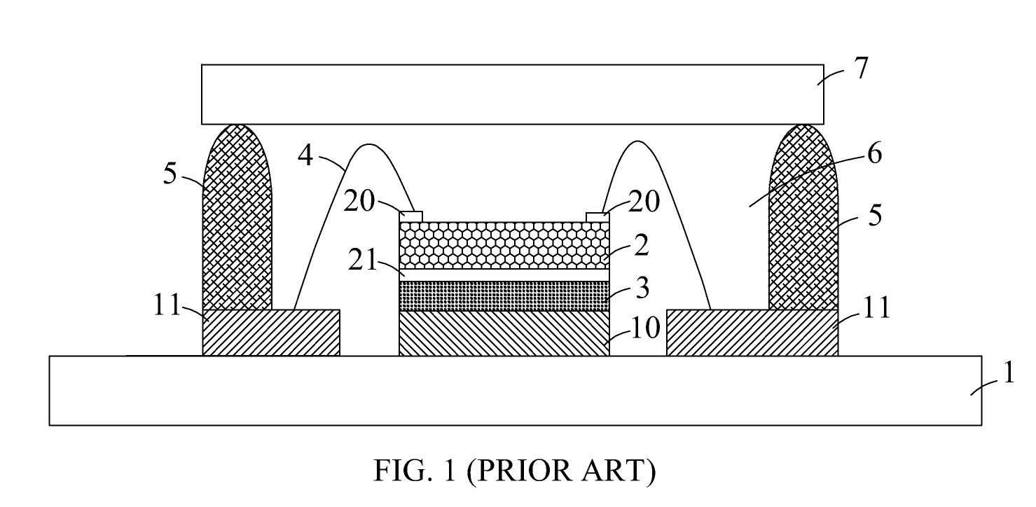

FIG. 2 is the cross-sectional view of the solar cell device of the present invention;

FIG. 3 is a schematic diagram of the layout of the electrode plate of the solar cell device of the present invention; and

FIG. 4 is the flowchart of a packaging method of the present invention.

### DESCRIPTION OF THE PREFERRED EMBODIMENTS

The embodiment of the present invention of the solar cell device and its packaging method is provided in the following detailed descriptions and related diagrams. It is noteworthy to point out that same numerals are used for representing respective same elements in the drawings.

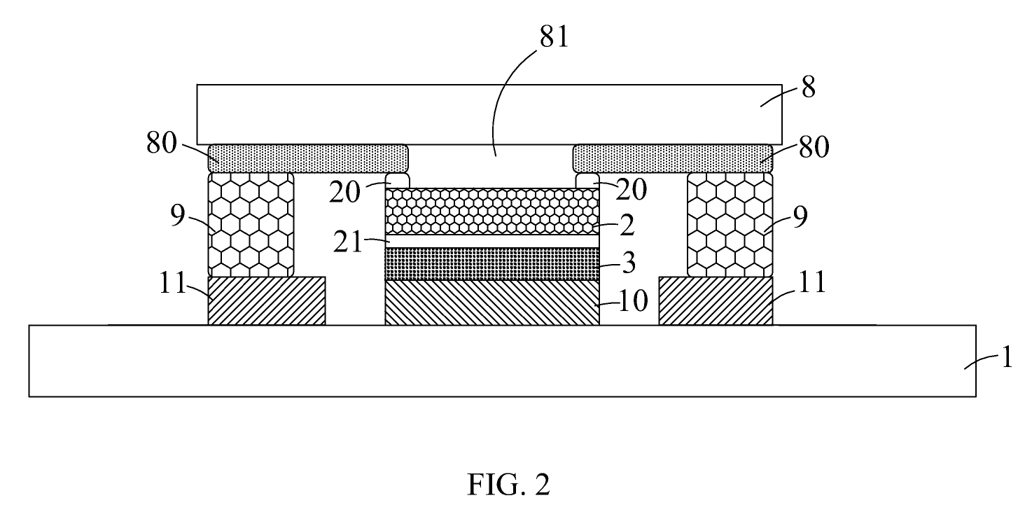

FIG. 2 illustrates the cross-sectional view of the solar cell device of the present invention. The diagram shows a concentrator photovoltaic cell device, comprising a circuit substrate 1, a positive electrode plate 10, a negative electrode plate 11, a solar cell chip 2, and an electrode plate 8. The circuit substrate 1 can be made of ceramic, on which the positive electrode plate 10 and the negative electrode plate 11 are disposed so that the ceramic circuit substrate has both positive and negative electrodes. There is a distance between the positive electrode plate 10 and the negative electrode plate 11, which is positioned on the corresponding two sides of the positive electrode plate 10. A front electrode 20 is installed on the two sides of the upper surface of the solar cell chip 2. A back electrode 21 is installed on the lower surface of the solar cell chip 2. As such, the solar cell chip 2 has both positive and negative electrodes.

The back electrode 21 of the solar cell chip 2 can be electrically connected with the positive electrode plate 10 of the circuit substrate 1 with the first electricity conducting adhesive material 3. The above-mentioned step connects the positive electrodes of the solar cell chip 2 and the circuit substrate 1. Then an ultrasonic soldering tool or any other equivalent soldering instrument can be used to melt a tin wire to form an electronic conducting element 80, which can be soldered on the two sides of the lower surface of a proper size glass substrate to form an electrode plate 8. Following the above step, the second electricity conducting adhesive material 9 is applied to the negative electrode plate 11 of the circuit substrate 1 and the front electrode 20 of the solar cell chip 2, then, aligning each electronic conducting element 80 to the negative electrode lines of the front electrode 20 and the negative electrode lines of the negative electrode plate 11, and then, covering the solar cell chip 2 with the electrode plate 8. The soldering tool is used to melt the second electricity conducting adhesive material 9 so that the electronic conducting elements 80 are connected with the negative electrode lines of the front electrode 20 and the negative electrode lines of the negative electrode plates 11 respectively. Then, the negative electrode of solar cell chip 2 is connected with the negative electrode of circuit substrate 1 so that the circuit between the solar cell chip 2 and the circuit substrate 1 is formed. It should be noted in the present invention that the first electricity conducting adhesive material 3 is only applied to glue the solar cell chip 2 and the circuit substrate 1 together, and the second electricity conducting adhesive material 9 is applied to glue the electrode plate 8, the solar cell chip 2, and the circuit substrate 1 only. This is mentioned as example rather than limitation.

Further, a high temperature tin paste, for example, with melting point of 217 degrees Celsius can be used as the first electricity conducting adhesive material 3, and a low temperature tin paste, for example, with melting point of 138 degrees Celsius can be used as the second electricity conducting adhesive material 9. So when the soldering tool is used to melt the second electricity conducting adhesive material 9, the first electricity conducting adhesive material 3 will not be melted. This prevents a possible loosened binding between the solar cell chip 2 and the circuit substrate 1.

In order to reduce the sunlight reflectivity from the solar cell chip 2, under the promise of that the solder between the electrode plate 8 and the front electrode 20 of the solar cell chip 2 is not affected, a minuscule amount of high light-transmissive adhesive colloid material 81 such as high light-transmissive silicone, with the property of low thickness and high-flow liquidity, can be applied on the surface of the solar cell chip 2 as a light transmission medium. This fact is mentioned here as an example to present the better current embodiment rather than a limitation.

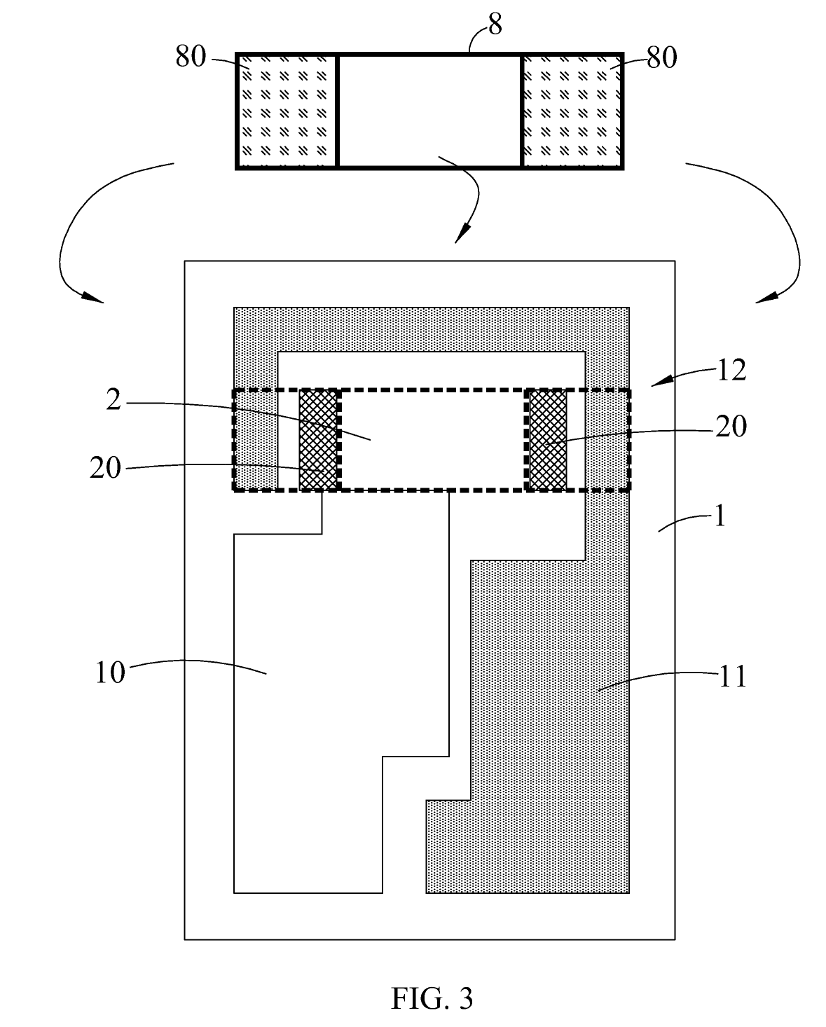

FIG. 3 is the schematic diagram of the layout of the electrode plate of the solar cell device of the present invention. The diagram shows a circuit substrate 1, a positive electrode plate 10, a negative electrode plate 11, a solar cell chip 2, and an electrode plate 8. The circuit substrate 1 can be made of ceramic, on which the positive electrode plate 10 and the negative electrode panel 11 are disposed so that the ceramic circuit substrate has both positive and negative electrodes. There is a distance between the positive electrode plate 10 and the negative electrode plate 11 preventing from connecting with each other. The sizes of the surface area, shape and positions of the positive electrode plate 10 and the negative electrode plate 11 can vary depending on the design of the solar cells.

In this embodiment, a die area 12 can be set on the circuit substrate 1, and the negative electrode plate 11 can be rendered into the shape similar to the character “U” and positioned near the positive electrode plate 10. That is to say, as the solar cell chip 2 is positioned on top of the positive electrode plate 10 to electrically connect with the circuit substrate 1, the negative electrode plate 11 wraps around the solar cell chip 2 in “U” layout. It should be noted that a front electrode 20 can be disposed respectively on the two sides of the upper surface of the solar cell chip 2. Hence, the negative electrode plate 11 is located on the one side of each front electrode 20. It should be noted and obvious to those who have a conventional knowledge of the solar cell field that the ceramic substrate applied in the present invention is cited as an example for explaining the embodiment and it is not set forth as a limitation. It should be obvious to those who have a conventional knowledge of the solar cell field that the circuit substrate 1 can be made of copper, aluminum, glass or other materials which can achieve the same required functions. It should be noted that the shapes, locations, and sizes of the positive electrode plate 10 and negative electrode plate 11 on the circuit substrate 1 mentioned in this embodiment serve as exemplar purpose rather than limitations.

In the embodiment of the electrode plate 8 of the present invention, a glass substrate with a proper size can be selected, and an electronic conducting element 80 can be fitted on the two sides of the lower surface of the glass substrate. The electronic conducting elements 80 can be made from heating tin wires by an ultrasonic soldering tool or any other equivalent soldering instruments. The positions of each of the electronic conducting elements 80 should be aligned to the negative electrode lines of the front electrode 20 and the negative electrode lines of the negative electrode plate 11. The solar cell chip 2 is covered with the electrode plate 8 in the semiconductor chip area 12 so that the electronic conducting element 80 can electrically connect respectively with the front electrodes 20 of the solar cell chip 2 and the negative electrode plate 11 of the circuit substrate 1. Hereby, the negative electrodes of the solar cell chip 2 can electrically connect with the negative electrode of the circuit substrate 1 to form a circuit loop of the solar cell device. It should be noted in the present embodiment that the tin wires, used to make the electronic conducting elements 80, is mentioned here as an example to better present the current embodiment rather than a limitation. Those who have a conventional understanding of the solar cell field should be aware that other materials such as copper, aluminum, silver or other devices with conductive efficiency can be applied to make the electronic conducting elements 80.

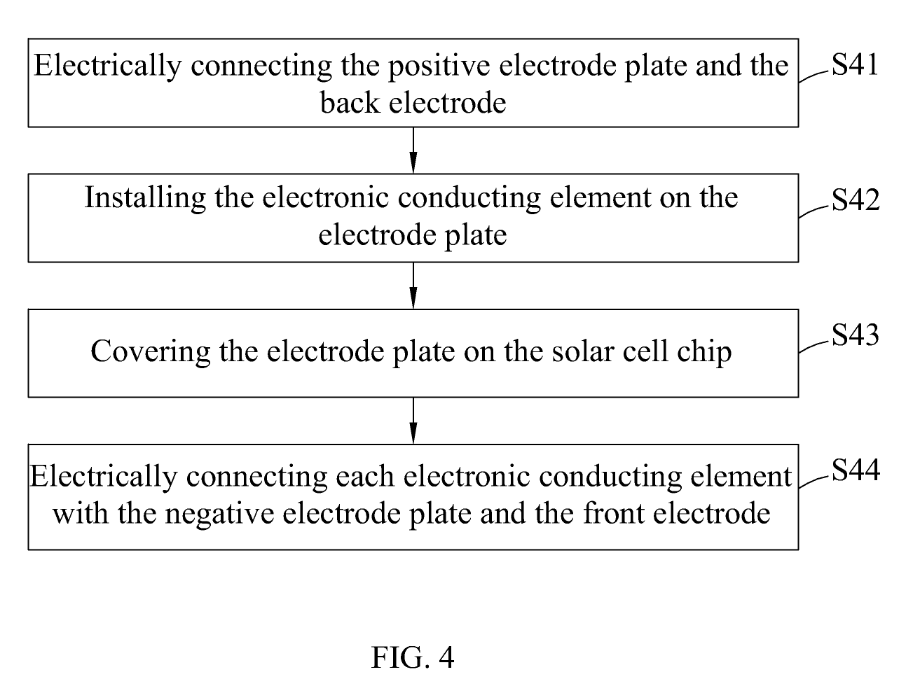

FIG. 4 is the flowchart of a packaging method of the present invention. As shown in the flowchart, the packaging method for the solar cell device described here is applied to the concentrator photovoltaic cells, wherein, the solar cell device comprises a circuit substrate, a solar cell chip, and an electrode plate. The packaging includes the following steps:

In step S41, applying the first electricity conducting adhesive material electrically connects with the positive electrode plate of the circuit substrate and the back electrode of the solar cell chip so that the positive electrode plate of the circuit substrate is connected with the positive electrode of the solar cell chip.

In step S42, disposing an electronic conducting element on the two sides of the lower surface of the electrode plate respectively.

In step S43, covering the solar cell chip with the electrode plate, and aligning each electronic conducting element with the front electrodes of the solar cell chip and the negative electrode plate of the circuit substrate.

In step S44, applying the second electricity conducting adhesive material electrically connects each electronic conducting element with the negative electrode lines of the negative electrode plate and the negative electrode lines of the front electrodes, so that the negative electrodes of the solar cell chip are connected with the negative electrodes of the circuit substrate to form a circuit loop of the solar cell device.

The detailed descriptions of the packaging method and the embodiments of the present invention are mentioned above.

In summation, the electrode plate is attached on the surface of the solar cell chip to provide a sound protection for the solar cell chip, as a result the height of the solar cell device of the present invention can be reduced to make the silicone layered measured within a range from 100 μm to 150 μm, which is substantially less than the height (1 mm to 1.5 mm) of that of the conventional solar cell devices. As such, the light concentrating device of the present invention is closer to the surface of the solar cell chip, and will have better light concentrating effects. Besides, the present invention reduces the use of light-transmissive silicone and generating bubbles, which could be generated by the conventional silicone-filling process and would reduce the sunlight entering the solar cell chip.

While particular embodiments of the present invention have been shown and described, it will be obvious to those skilled in the art that, based upon the teachings herein, changes and modifications may be made without departing from this invention and its broader aspects. Therefore, the appended claims are intended to encompass within their scope of all such changes and modifications as are within the true spirit and scope of the exemplary embodiment(s) of the present invention.

What is claimed is:

1. A solar cell device applicable to a concentrator photovoltaic cell, including:
a circuit substrate including a die area;
a positive electrode plate disposed on the die area;
a negative electrode plate positioned on the die area and located on two sides of the positive electrode plate;
a solar cell chip respectively disposed a front electrode on two sides of an upper surface of the solar cell chip and disposed a back electrode on a lower surface of the solar cell chip, and the back electrode electrically connected with the positive electrode plate; and
an electrode plate respectively disposed an electronic conducting element on two sides of a lower surface of the electrode plate, and each of the electronic conducting elements electrically connected with each of the front electrodes and the negative electrode plate respectively.

2. The solar cell device of claim 1, wherein the back electrode further includes a first electricity conducting adhesive material electrically connecting to the positive electrode plate.

3. The solar cell device of claim 2, wherein each of the electronic conducting elements electrically connects to each of the front electrodes and the negative electrode plate through a second electricity conducting adhesive material.

4. The solar cell device of claim 3, wherein a melting point of the first electricity conducting adhesive material is higher than a melting point of the second electricity conducting adhesive material.

5. The solar cell device of claim 1, wherein a light-transmissive colloid material is disposed between the electrode plate and the solar cell chip.

6. The solar cell device of claim 1, wherein the circuit substrate further includes a ceramic circuit substrate.

7. The solar cell device of claim 1, wherein the electrode plate further includes a transparent electrode plate.

8. The solar cell device of claim 7, wherein the transparent electrode plate further includes a glass electrode plate.

9. The solar cell device of claim 1, wherein each of the electronic conducting elements further includes a metal material.

10. A solar cell device packaging method applicable to an encapsulating process of a solar cell device of a concentrator photovoltaic cell, the solar cell device comprising a circuit substrate, a solar cell chip, and an electrode plate, and the packaging method comprising steps of:
disposing a positive electrode plate on a die area of the circuit substrate;
disposing a negative electrode plate corresponding to two sides of the positive electrode plate;
disposing a front electrode on two sides of an upper surface of the solar cell chip respectively;
disposing a back electrode on a lower surface of the solar cell chip;
connecting electrically with the back electrode and the positive electrode plate;
disposing an electronic conducting element on two sides of a lower surface of the electrode plate respectively; and
connecting electrically each of the conducting elements with each of the front electrodes and the negative electrode plate, respectively.

11. The solar cell device packaging method of claim 10 further comprising a step of: applying a first electricity conducting adhesive material to electrically connect the back electrode and the positive electrode plate.

12. The solar cell device packaging method of claim 11, further comprising a step of applying a second electricity conducting adhesive material to make each of the electronic conducting elements electrically connecting to each of the front electrodes and the negative plate respectively.

13. The solar cell device packaging method of claim 12, wherein a melting point of the first electricity conducting adhesive material is higher than a melting point of the second electricity conducting adhesive material.

14. The solar cell device packaging method of claim 10, further comprising a step of disposing a light-transmissive colloid material between the electrode plate and the solar cell chip.
